(19) United States
(12) Patent Application Publication
(10) Pub. No.: US 2025/0219033 A1
(43) Pub. Date: Jul. 3, 2025

(54) HYBRID BONDING STRUCTURE AND DISPLAY PANEL

(71) Applicant: Industrial Technology Research Institute, Hsinchu (TW)

(72) Inventors: Jui-Wen Yang, New Taipei City (TW); Chieh-Wei Feng, Taoyuan City (TW); Chih Wei Lu, Taoyuan City (TW); Hsien-Wei Chiu, Taoyuan City (TW); Tai-Jui Wang, New Taipei City (TW)

(73) Assignee: Industrial Technology Research Institute, Hsinchu (TW)

(21) Appl. No.: 18/432,086

(22) Filed: Feb. 5, 2024

(30) Foreign Application Priority Data
Dec. 27, 2023 (TW) 112151004

(51) Int. Cl. H01L 25/16; H01L 23/00; H01L 23/13; H01L 23/538

(52) U.S. Cl. CPC H01L 25/167; H01L 23/5385; H01L 23/5389; H01L 24/20; H01L 25/162; H01L 23/13; H01L 24/24; H01L 2224/211; H01L 2224/215; H01L 2224/24137; H01L 2924/01029; H01L 2924/12041; H01L 2924/1426

(57) ABSTRACT

A bonding structure, including a first dielectric layer, multiple first conductors, a second dielectric layer, and multiple second conductors, is provided. The first conductors are embedded in the first dielectric layer, the first dielectric layer is bonded with the second dielectric layer, and the second conductors are embedded in the second dielectric layer, wherein the first conductors are bonded with the second conductors, and a bonding interface between the first conductors and the second conductors is a bonding interface containing silver.

### CROSS-REFERENCE TO RELATED APPLICATION

This application claims the priority benefit of Taiwan application serial no. 112151004, filed on Dec. 27, 2023. The entirety of the above-mentioned patent application is hereby incorporated by reference herein and made a part of this specification.

### TECHNICAL FIELD

The disclosure relates to a display panel.

### BACKGROUND

In response to the applications of augmented reality (AR) and mixed reality (MR), the demand for ultra-high-resolution display panels using micro-light emitting diode (micro-LED) chips is increasing. Currently, advanced display devices applied in augmented reality and mixed reality often face issues such as unevenness and chip displacement during assembly, thereby causing issues such as display mura and poor reliability.

### SUMMARY

A hybrid bonding structure and a display panel are introduced herein.

A hybrid bonding structure according to an embodiment of the disclosure includes a first dielectric layer, multiple first conductors, a second dielectric layer, and multiple second conductors. The first conductors are embedded in the first dielectric layer, the second dielectric layer is bonded with the first dielectric layer, and the second conductors are embedded in the second dielectric layer. The second conductors are bonded with the first conductors, and a bonding interface between the second conductors and the first conductors is a bonding interface containing silver.

A display panel according to another embodiment of the disclosure includes a hybrid bonding structure, a first redistribution structure, a second redistribution structure, multiple light emitting chips, and multiple driving chips. The first redistribution structure and the second redistribution structure are respectively located on opposite sides of the hybrid bonding structure, and the first redistribution structure is electrically connected to the second redistribution structure through the hybrid bonding structure. The driving chips are electrically connected to the light emitting chips through at least one of the first redistribution structure and the second redistribution structure.

A display panel according to another embodiment of the disclosure includes a redistribution structure, multiple light emitting chips, multiple driving chips, and a carrying substrate. The light emitting chips are embedded in the redistribution structure, and the driving chips are equipped on the redistribution structure. The driving chips are electrically connected to the light emitting chips through the redistribution structure, and the driving chips are located between the redistribution structure and the carrying substrate.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a schematic cross-sectional view of a display panel according to a first embodiment of the disclosure.

FIG. 2 is a schematic cross-sectional view of a display panel according to a second embodiment of the disclosure.

FIG. 3 is a schematic cross-sectional view of a display panel according to a third embodiment of the disclosure.

FIG. 4 is a schematic cross-sectional view of a display panel according to a fourth embodiment of the disclosure.

FIG. 5 is a schematic cross-sectional view of a display panel according to a fifth embodiment of the disclosure.

FIG. 6 is a schematic cross-sectional view of a display panel according to a sixth embodiment of the disclosure.

FIG. 7 is a schematic cross-sectional view of a display panel according to a seventh embodiment of the disclosure.

FIG. 8 is a schematic cross-sectional view of a display panel according to an eighth embodiment of the disclosure.

FIG. 9 is a schematic cross-sectional view of a display panel according to a ninth embodiment of the disclosure.

FIG. 10 is a schematic cross-sectional view of a display panel according to a tenth embodiment of the disclosure.

FIG. 11 is a schematic cross-sectional view of a display panel according to an eleventh embodiment of the disclosure.

FIG. 12 is a schematic cross-sectional view of a display panel according to a twelfth embodiment of the disclosure.

FIG. 13 is a schematic cross-sectional view of a display panel according to a thirteenth embodiment of the disclosure.

FIG. 14 is a schematic cross-sectional view of a display panel according to a fourteenth embodiment of the disclosure.

FIG. 15 is a schematic cross-sectional view of a display panel according to a fifteenth embodiment of the disclosure.

FIG. 16 is a schematic cross-sectional view of a hybrid bonding structure before a hybrid bonding interface thereof is formed according to an embodiment of the disclosure.

FIG. 17 is a schematic cross-sectional view of a display panel according to a sixteenth embodiment of the disclosure.

FIG. 18 is a schematic cross-sectional view of a display panel according to a seventeenth embodiment of the disclosure.

FIG. 19 is a schematic cross-sectional view of a display panel according to an eighteenth embodiment of the disclosure.

### DETAILED DESCRIPTION OF DISCLOSURE EMBODIMENTS

Embodiments are enumerated below and described in detail with reference to the drawings. However, the embodiments provided are not intended to limit the scope of the disclosure. In addition, the drawings are for illustrative purposes only and are not drawn to original size. To facilitate understanding, the same elements will be identified with the same reference numerals in the following description. In addition, terms such as “contain”, “include”, and “have” used herein are all open terms, which means “comprising but not limited to”. Furthermore, directional terms such as “upper” and “lower” mentioned herein are only used with reference to the direction of the drawings and are not used to limit the disclosure. In addition, numbers and shapes mentioned in the specification are only used to specifically illustrate the disclosure to facilitate understanding of the content, but are not used to limit the disclosure.

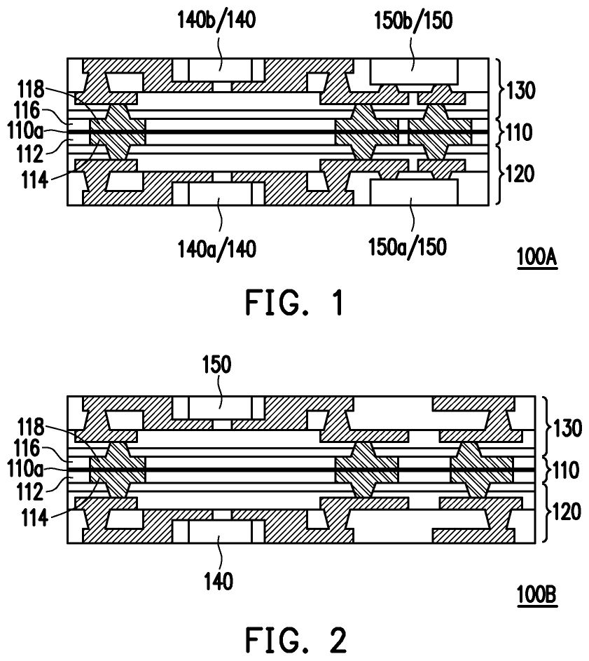

FIG. 1 is a schematic cross-sectional view of a display panel 100A according to a first embodiment of the disclosure.

Please refer to FIG. 1. The display panel 100A of the embodiment includes a hybrid bonding structure 110, a first redistribution structure 120, a second redistribution structure 130, multiple light emitting chips 140, and multiple driving chips 150. The first redistribution structure 120 and the second redistribution structure 130 are respectively located on opposite sides of the hybrid bonding structure 110, and the first redistribution structure 120 is electrically connected to the second redistribution structure 130 through the hybrid bonding structure 110. In addition, the driving chips 150 are electrically connected to the light emitting chips 140 through the first redistribution structure 120, the hybrid bonding structure 110, and the second redistribution structure 130.

In the embodiment, the light emitting chips 140 include multiple first light emitting chips 140a and multiple second light emitting chips 140b, and the driving chips 150 include at least one first driving chip 150a and at least one second driving chip 150b, wherein the first light emitting chips 140a and the first driving chip 150a are embedded in the first redistribution structure 120, the first driving chip 150a may be electrically connected to the first light emitting chips 140a through the first redistribution structure 120, the second light emitting chips 140b and the second driving chip 150b are embedded in the second redistribution structure 130, and the second driving chip 150b may be electrically connected to the second light emitting chips 140b through the second redistribution structure 130. In some embodiments, in addition to being electrically connected to the first light emitting chips 140a, the first driving chip 150a may also be electrically connected the second light emitting chips 140b through the first redistribution structure 120, the hybrid bonding structure 110, and the second redistribution structure 130, and in addition to being electrically connected to the second light emitting chips 140b, the second driving chip 150b may also be electrically connected to the first light emitting chips 140a through the first redistribution structure 120, the hybrid bonding structure 110, and the second redistribution structure 130. In other embodiments, one of the first driving chip 150a and the second driving chip 150b may be omitted. In other words, the display panel 100A may only have the first driving chip 150a or the second driving chip 150b to control the first light emitting chips 140a and the second light emitting chips 140b. As shown in FIG. 1, in the embodiment, the display panel 100A including the first light emitting chips 140a and the second light emitting chips 140b has a double-sided display function.

In some embodiments, the hybrid bonding structure 110 includes a first dielectric layer 112, multiple first conductors 114 embedded in the first dielectric layer 112, a second dielectric layer 116, and multiple second conductors 118 embedded in the second dielectric layer 116, wherein the second dielectric layer 116 is bonded with the first dielectric layer 112, the second conductors 118 are bonded with the first conductors 114, and a bonding interface 110a between the second conductors 118 and the first conductors 114 is a bonding interface containing silver. For example, the main materials of the second conductors 118 and the first conductors 114 include copper or other suitable conductive materials, the materials of the first dielectric layer 112 and the second dielectric layer 116 include silicon dioxide or other suitable dielectric materials, and the bonding interface 110a located between the second conductors 118 and the first conductors 114 includes a copper-silver alloy bonding interface. The presence of silver metal not only does not affect the bonding between the first dielectric layer 112 and the second dielectric layer 116, but also facilitates the bonding between the second conductors 118 and the first conductors 114, which are both made of copper metal materials. Based on the above, a copper-silver alloy produced during the bonding process of the second conductors 118 and the first conductors 114 facilitates the improvement of the bonding stability between the second conductors 118 and the first conductors 114.

In the embodiment, the elongation of the first dielectric layer 112 of the hybrid bonding structure 110 is approximately between 10% and 85%, the Young's modulus of the first dielectric layer 112 of the hybrid bonding structure 110 is approximately between 2.5% and 3.2%, and the tensile strength of the first dielectric layer 112 of the hybrid bonding structure 110 is greater than 110 MPa. In addition, the elongation of the second dielectric layer 116 of the hybrid bonding structure 110 is approximately between 10% and 85%, the Young's modulus of the second dielectric layer 116 of the hybrid bonding structure 110 is approximately between 2.5% and 3.2%, and the tensile strength of the second dielectric layer 116 of the hybrid bonding structure 110 is greater than 110 MPa.

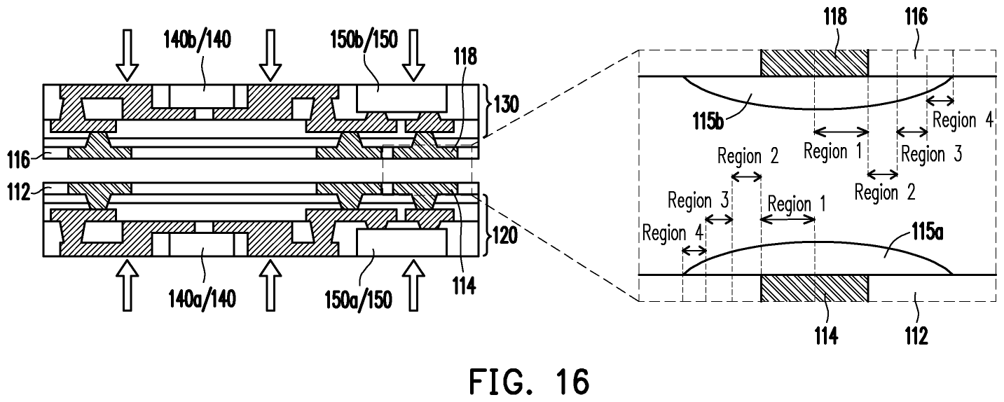

In the embodiment, as shown in FIG. 1 and FIG. 16, the manufacturing of a lower half portion of the display panel 100A includes the following steps. First, the first light emitting chips 140a and the first driving chip 150a are placed on a carrier. Then, the first redistribution structure 120 is formed on the carrier, wherein the first redistribution structure 120 covers the first light emitting chips 140a and the first driving chip 150a and is electrically connected to the first light emitting chips 140a and the first driving chip 150a. After that, a first bonding structure is formed on the first redistribution structure 120, and the first bonding structure includes the first dielectric layer 112 and the first conductors 114 penetrating the first dielectric layer 112, wherein surfaces of the first conductors 114 may be plated with a silver metal layer 115a. Considering that the first light emitting chips 140a and the first driving chip 150a are placed before the first redistribution structure 120 is manufactured, the embodiment may ensure that the first redistribution structure 120 can be correctly electrically connected to the first light emitting chips 140a and the first driving chip 150a using dynamic die shift correction (DDC) technology. For example, in the case where the minimum line width of a line is 2 μm, the shift of the line can be less than 50 μm and the shift of a rotational angle can be less than 0.3 degrees through the shift correction technology.

In the embodiment, the manufacturing of an upper half portion of the display panel 100A includes the following steps. First, the second light emitting chips 140b and the second driving chip 150b are placed on a carrier. Then, the second redistribution structure 130 is formed on the carrier, wherein the second redistribution structure 130 covers the second light emitting chips 140b and the second driving chip 150b and is electrically connected to the second light emitting chips 140b and the second driving chip 150b. After that, a second bonding structure is formed on the second redistribution structure 130, and the second bonding structure includes the second dielectric layer 116 and the second conductors 118 penetrating the second dielectric layer 116, wherein surfaces of the second conductors 114 may be plated with another silver metal layer 115b. Considering that the second light emitting chips 140b and the second driving chip 150b are placed before the second redistribution structure 130 is manufactured, the embodiment may ensure that the second redistribution structure 130 can be correctly electrically connected to the second light emitting chips 140b and the second driving chip 150b using the dynamic die shift correction technology.

As shown in FIG. 16, the silver metal layer 115a respectively has different average thicknesses in different regions (that is, a region 1, a region 2, a region 3, and a region 4), wherein the region 1, the region 2, the region 3, and the region 4 are defined by lateral distances from a center of the first conductor 114, wherein a lateral size of the first conductor 114 is A, the region 1 refers to a region where the lateral distance from the center of the first conductor 114 is between 0 and 0.5A, the region 2 refers to a region where the lateral distance from the center of the first conductor 114 is between 0.5A and 0.75A, the region 3 refers to a region where the lateral distance from the center of the first conductor 114 is between 0.75A and 1A, and the region 4 refers to a region where the lateral distance from the center of the first conductor 114 is greater than 1A. For example, the average thickness of the silver metal layer 115a located in the region 1 is B, the average thickness of the silver metal layer 115a located in the region 2 is 0.63B, the average thickness of the silver metal layer 115a located in the region 3 is 0.56B, and the average thickness of the silver metal layer 115a located in the region 4 is 0.34B. Similarly, the silver metal layer 115b respectively has different average thicknesses in different regions (that is, a region 1, a region 2, a region 3, and a region 4), wherein the region 1, the region 2, the region 3, and the region 4 are defined by lateral distances from a center of the second conductor 118, wherein a lateral size of the second conductor 118 is A, the region 1 refers to a region where the lateral distance from the center of the second conductor 118 is between 0 and 0.5A, the region 2 refers to a region where the lateral distance from the center of the second conductor 118 is between 0.5A and 0.75A, the region 3 refers to a region where the lateral distance from the center of the second conductor 118 is between 0.75A and 1A, and the region 4 refers to a region where the lateral distance from the center of the second conductor 118 is greater than 1A. For example, the average thickness of the silver metal layer 115b located in the region 1 is B, the average thickness of the silver metal layer 115b located in the region 2 is 0.63B, the average thickness of the silver metal layer 115b located in the region 3 is 0.56B, and the average thickness of the silver metal layer 115b located in the region 4 is 0.34B.

The lower half portion and the upper half portion of the display panel 100A are aligned and bonded with each other, so that the first conductors 114 and the second conductors 118 are bonded with each other by the silver metal layer 115a and the silver metal layer 115b, and the first dielectric layer 112 and the second dielectric layer 116 are bonded with each other (that is, dielectric layer-to-dielectric layer bonding). In addition, after the lower half portion and the upper half portion of the display panel 100A are bonded with each other, the total thickness of the silver metal layer 115a and the silver metal layer 115b changes. For example, the total thickness of the silver metal layer 115a and the silver metal layer 115b located in the region 1, the region 2, and the region 3 is about 1.5B, and the total thickness of the silver metal layer 115a and the silver metal layer 115b located in the region 4 is about 0.51B.

In some embodiments, an active element and/or a passive element may be manufactured with a film process in the hybrid bonding structure 110, and the passive element and/or the active element operate together with the first driving chip 150a and the second driving chip 150b to drive the first light emitting chips 140a and the second light emitting chips 140b to perform display. In addition, a metal barrier layer may be manufactured during the manufacturing process of the first redistribution structure 120 and/or the second redistribution structure 130 to prevent a conductor (for example, a metal circuit) in the first redistribution structure 120 and/or the second redistribution structure 130 from affecting the subsequent film process for forming the active element and/or the passive element.

FIG. 2 is a schematic cross-sectional view of a display panel 100B according to a second embodiment of the disclosure. Please refer to FIG. 1 and FIG. 2. The display panel 100B of the embodiment is similar to the display panel 100A of the first embodiment. The main difference between the two is that the light emitting chips 140 in the display panel 100B are embedded in the first redistribution structure 120, the driving chips 150 are embedded in the second redistribution structure 130, and the driving chips 150 are electrically connected to the light emitting chips 140 through the second redistribution structure 130, the hybrid bonding structure 110, and the first redistribution structure 120. In other words, in the embodiment, the display panel 100B including the light emitting chips 140 only has a single-sided display function.

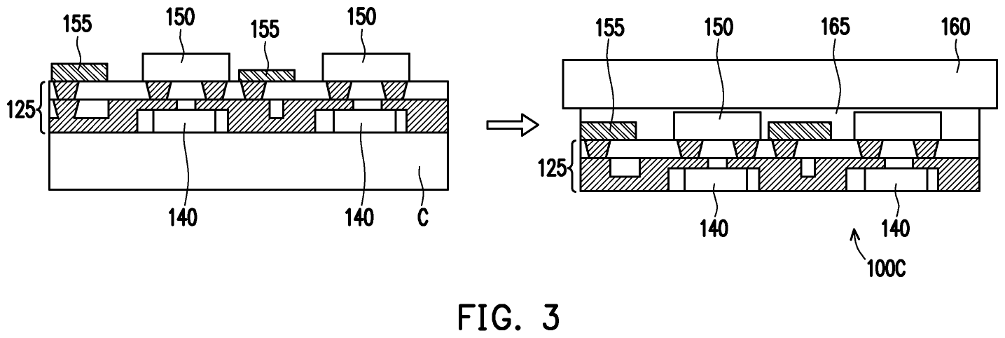

FIG. 3 is a schematic cross-sectional view of a display panel 100C according to a third embodiment of the disclosure. Please refer to a left half portion of FIG. 3. First, the light emitting chips 140 are placed on a carrier C. Next, a redistribution structure 125 is formed on the carrier C, wherein the redistribution structure 125 covers the light emitting chips 140 and is electrically connected to the light emitting chips 140. After that, the driving chips 150 are placed on the redistribution structure 125, and the driving chips 150 are electrically connected to the redistribution structure 125. In addition to placing the driving chips 150, a passive element 155 may be selectively placed on the redistribution structure 125, the passive element 155 is electrically connected to the redistribution structure 125, and the passive element 155 operates together with the driving chips 150 to drive the light emitting chips 140 to perform display. Considering that the light emitting chips 140 are placed before the redistribution structure 125 is manufactured, the embodiment may ensure that the redistribution structure 125 can be correctly electrically connected to the light emitting chips 140 using the dynamic die shift correction technology.

Please refer to a right half portion of FIG. 3. Next, a carrying substrate 160 is provided, and an adhesion layer 165 is provided between the redistribution structure 125 and the carrying substrate 160, so that the redistribution structure 125, the light emitting chips 140, the driving chips 150, and the passive element 155 formed on the carrier C are transferred onto the carrying substrate 160. After the transferring process, the adhesion layer 165 covers the driving chips 150 and the passive element 155. Afterwards, a de-bonding process of the carrier C may be selectively performed, so that the redistribution structure 125 and the light emitting chips 140 are de-bonded from the carrier C.

As shown in the right half portion of FIG. 3, the display panel 100C of the embodiment includes the redistribution structure 125, the light emitting chips 140, the driving chips 150, and the carrying substrate 160. The light emitting chips 140 are embedded in the redistribution structure 125, and the driving chips 150 are equipped on the redistribution structure 125, wherein the driving chips 150 are electrically connected to the light emitting chips 140 through the redistribution structure 125, and the driving chips 150 are located between the redistribution structure 125 and the carrying substrate 160. In the embodiment, the driving chips 150 may be located above the light emitting chips 140, and the carrying substrate 160 may include a printed circuit board, a semiconductor wafer, a glass substrate, a ceramic substrate, etc.

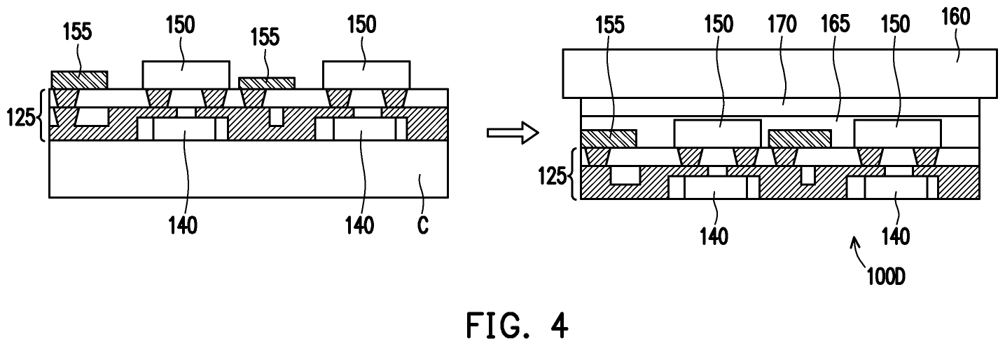

FIG. 4 is a schematic cross-sectional view of a display panel 100D according to a fourth embodiment of the disclosure. Please refer to FIG. 3 and FIG. 4. The display panel 100D of the embodiment is similar to the display panel 100C of the third embodiment. The main difference between the two is that the display panel 100D further includes a stress compensation layer 170, and the stress compensation layer 170 is disposed between the driving chips 150 and the carrying substrate 160 or between the adhesion layer 165 and the carrying substrate 160.

In the embodiment, the stress compensation layer 170 may be used to improve the warpage of the display panel 100D. The stress compensation layer 170 may also be applied in a display panel according to other embodiments of the disclosure.

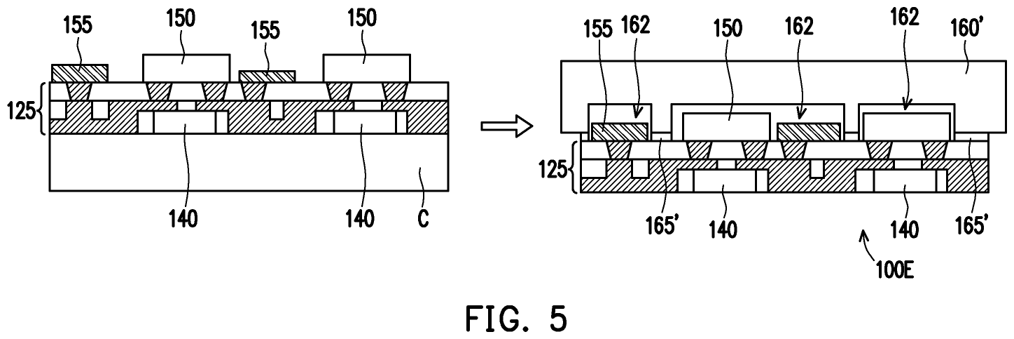

FIG. 5 is a schematic cross-sectional view of a display panel 100E according to a fifth embodiment of the disclosure. Please refer to FIG. 3 and FIG. 5. The display panel 100E of the embodiment is similar to the display panel 100C of the third embodiment. The main difference between the two is that the forms of a carrying substrate 160′ and an adhesion layer 165′ in the display panel 100E are different.

As shown in FIG. 5, the carrying substrate 160′ includes a groove 162, the driving chips 150 and the passive element 155 are located in the groove 162, and the carrying substrate 160′ is adhered to the redistribution structure 125 by the adhesion layer 165′. In addition, the driving chips 150 and the passive element 155 maintain a specific distance from the carrying substrate 160′. In other words, the carrying substrate 160′ is not in contact with the driving chips 150 and the passive element 155.

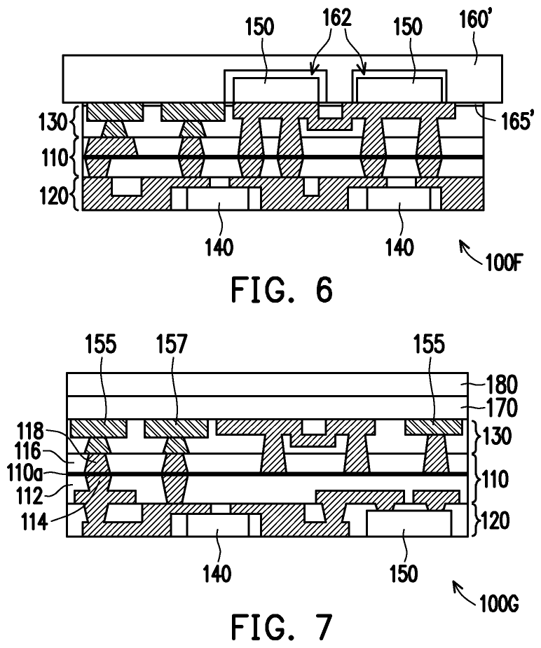

FIG. 6 is a schematic cross-sectional view of a display panel 100F according to a sixth embodiment of the disclosure. Please refer to FIG. 2 and FIG. 6. The display panel 100F of the embodiment is similar to the display panel 100B of the second embodiment. The main difference between the two is that in the display panel 100F, the light emitting chips 140 are embedded in the first redistribution structure 120, the driving chips 150 are disposed on the second redistribution structure 130, and the light emitting chips 140 are electrically connected to the driving chips 150 through the first redistribution structure 120, the hybrid bonding structure 110, and the second redistribution structure 130. In addition, the forms of the carrying substrate 160′ and the adhesion layer 165′ in the display panel 100F are similar to the forms of the carrying substrate 160′ and the adhesion layer 165′ in the display panel 100E, so there is no reiteration here.

FIG. 7 is a schematic cross-sectional view of a display panel 100G according to a seventh embodiment of the disclosure. Please refer to FIG. 1 and FIG. 7. The display panel 100G of the embodiment is similar to the display panel 100A of the first embodiment. The main difference between the two is that the light emitting chips 140 and the driving chips 150 are embedded in the first redistribution structure 120, the light emitting chips 140 are electrically connected to the driving chips 150 through the first redistribution structure 120, the passive element 155 and/or the active element 157 is embedded in the second redistribution structure 130, and the passive element 155 and/or the active element 157 is electrically connected to the second redistribution structure 130. The passive element 155 and/or the active element 157 may be regarded as a chip-form electronic element. In the embodiment, the passive element 155 and/or the active element 157 operates together with the driving chips 150 to drive the light emitting chips 140 to perform display.

As shown in FIG. 7, the display panel 100G may further include the stress compensation layer 170, and the stress compensation layer 170 is disposed between the second redistribution structure 130 and a carrying film 180. In the embodiment, the stress compensation layer 170 may be used to improve the warpage of the display panel 100G, the carrying film 180 is a flexible material layer, and the material of the carrying film 180 includes a polyimide film or other flexible dielectric materials. The combination of the stress compensation layer 170 and the carrying film 180 may also be applied in a display panel according to other embodiments of the disclosure.

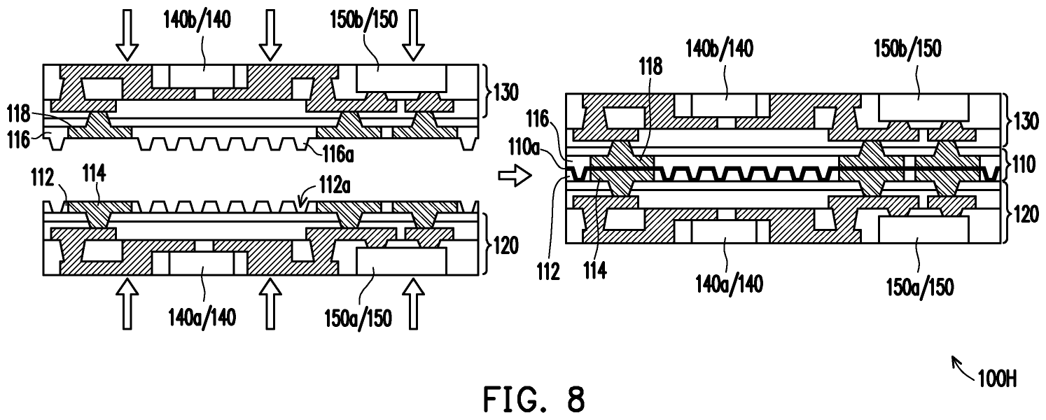

FIG. 8 is a schematic cross-sectional view of a display panel 100H according to an eighth embodiment of the disclosure. Please refer to FIG. 1 and FIG. 8. The display panel 100H of the embodiment is similar to the display panel 100A of the first embodiment. The main difference between the two is that the first dielectric layer 112 has multiple grooves 112a, the second dielectric layer 116 has multiple protrusions 116a, and the protrusions 116a are embedded in the grooves 112a. In addition, it can be seen from FIG. 8 that the bonding interface 110a is a zigzag-shaped bonding interface, and the zigzag-shaped bonding interface can effectively increase a bonding area between the first dielectric layer 112 and the second dielectric layer 116.

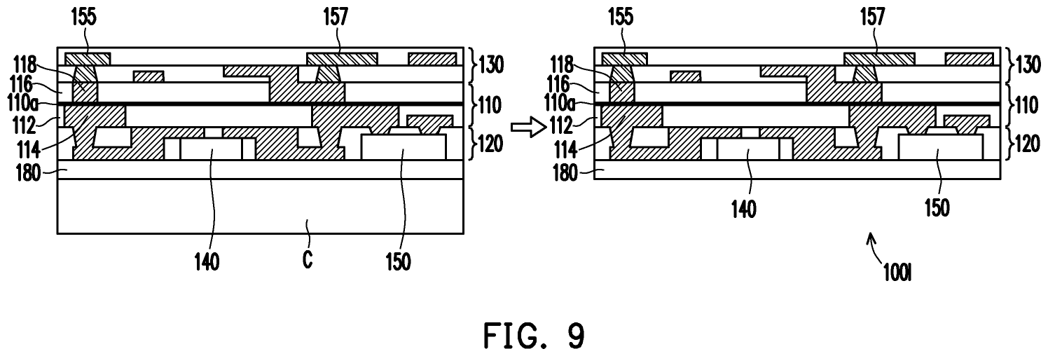

FIG. 9 is a schematic cross-sectional view of a display panel 100I according to a ninth embodiment of the disclosure. Please refer to FIG. 7 and FIG. 9. The display panel 100I of the embodiment is similar to the display panel 100G of the seventh embodiment. The main difference between the two is that the carrying film 180 in the display panel 100I is disposed on a lower surface in the first redistribution structure 120.

Please refer to a left half portion of FIG. 9. The manufacturing of a lower half portion of the display panel 100I includes the following steps. First, the light emitting chips 140 and the driving chips 150 are placed on the carrier C formed with the carrying film 180. Here, the light emitting chips 140 and the driving chips 150 are placed on a surface of the carrying film 180. The carrying film 180 is a flexible material layer, and the material of the carrying film 180 includes a polyimide film or other flexible dielectric materials. Next, the first redistribution structure 120 is formed on the carrier C, wherein the first redistribution structure 120 covers the light emitting chips 140 and the driving chips 150 and is electrically connected to the light emitting chips 140 and the driving chips 150. After that, the first bonding structure is formed on the first redistribution structure 120, and the first bonding structure includes the first dielectric layer 112 and the first conductors 114 penetrating the first dielectric layer 112. Here, the first dielectric layer 112 includes a photosensitive polyimide film. As shown in FIG. 9, the light emitting chips 140 are electrically connected to the driving chips 150 through the first redistribution structure 120. Considering that the light emitting chips 140 and the driving chips 150 are placed before the first redistribution structure 120 is manufactured, the embodiment may ensure that the first redistribution structure 120 can be correctly electrically connected to the light emitting chips 140 and the driving chips 150 using the dynamic die shift correction technology.

In the embodiment, the manufacturing of an upper half portion of the display panel 100I includes the following steps. First, the second redistribution structure 130, the passive element 155, and/or the active element 157 are formed on another carrier (not shown), wherein the passive element 155 and/or the active element 157 is embedded in the second redistribution structure 130, and the passive element 155 and/or the active element 157 is electrically connected to the second redistribution structure 130. In some embodiments, the passive element 155 and/or the active element 157 may be formed during the manufacturing process of the second redistribution structure 130 by the film process or the chip-form passive element 155 and/or active element 157 may be placed in the second redistribution structure 130 during the manufacturing process of the second redistribution structure 130. Next, the second bonding structure is formed on the second redistribution structure 130, and the second bonding structure includes the second dielectric layer 116 and the second conductors 118 penetrating the second dielectric layer 116. Here, the second dielectric layer 116 includes the photosensitive polyimide film.

The lower half portion and the upper half portion of the display panel 100I are aligned and bonded with each other, so that the first conductors 114 and the second conductors 118 are bonded with each other (that is, metal-to-metal bonding), and the first dielectric layer 112 and the second dielectric layer 116 are bonded with each other (that is, dielectric layer-to-dielectric layer bonding). In some embodiments, the passive element 155 and/or the active element 157 located in the second redistribution structure 130 operates together with the driving chips 150 to drive the light emitting chips 140 to perform display.

Please refer to the right half portion of FIG. 9. The de-bonding process of the carrier C is performed, so that the carrying film 180 is de-bonded from the carrier C.

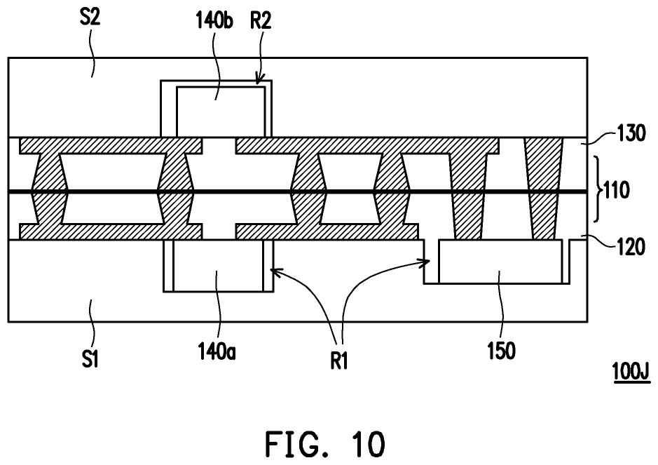

FIG. 10 is a schematic cross-sectional view of a display panel 100J according to a tenth embodiment of the disclosure. Please refer to FIG. 1 and FIG. 10. The display panel 100J of the embodiment is similar to the display panel 100A of the first embodiment. The main difference between the two is that the display panel 100J further includes a first substrate S1 disposed on a lower surface of the first redistribution structure 120 and a second substrate S2 disposed on an upper surface of the second redistribution structure 130, wherein the first redistribution structure 120 and the second redistribution structure 130 are located between the first substrate S1 and the second substrate S2. In addition, the first substrate S1 has a groove R1 accommodating the first light emitting chips 140a and the driving chips 150, the second substrate S2 has a groove R2 accommodating the second light emitting chips 140b, and the first light emitting chips 140a and the second light emitting chips 140b are respectively electrically connected to the driving chips 150 through the first redistribution structure 120, the hybrid bonding structure 110, and the second redistribution structure 130. In some embodiments, the first substrate S1 and the second substrate S2 include glass substrates, and the grooves R1 and R2 in the first substrate S1 and the second substrate S2 facilitate the reduction of the overall thickness of the display panel 100J.

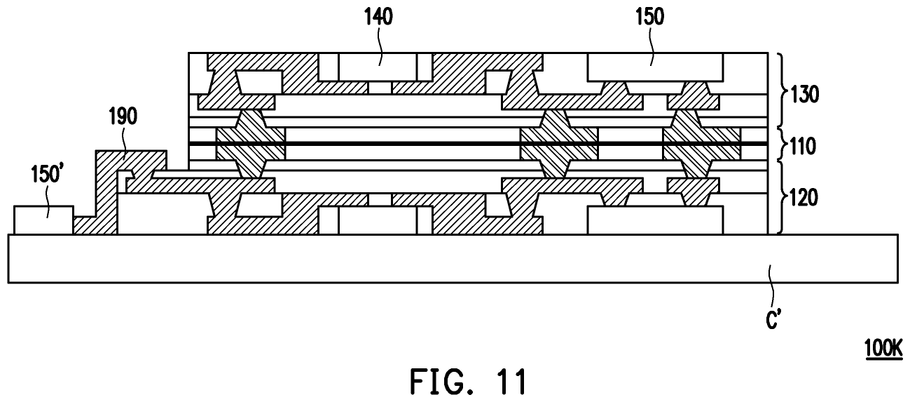

FIG. 11 is a schematic cross-sectional view of a display panel 100K according to an eleventh embodiment of the disclosure. Please refer to FIG. 1 and FIG. 11. The display panel 100K of the embodiment is similar to the display panel 100A of the first embodiment. The main difference between the two is that in the display panel 100K, the width of the first redistribution structure 120 is greater than the width of the second redistribution structure 130. In addition, the first redistribution structure 120 is disposed on a carrier C′, and the display panel 100K further includes a connecting conductive line 190 and a driving chip 150′, wherein the first redistribution structure 120 is electrically connected to the driving chip 150′ on the carrier C′ through the connecting conductive line 190.

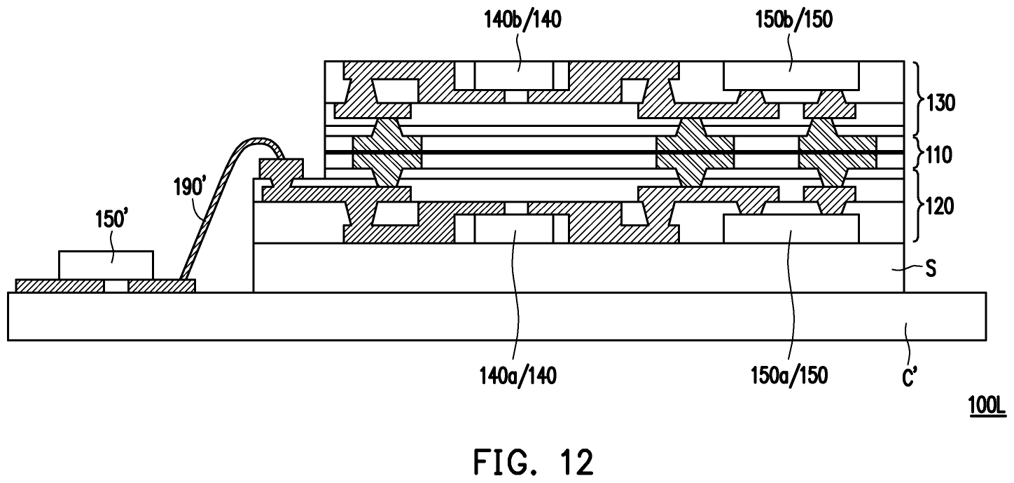

FIG. 12 is a schematic cross-sectional view of a display panel 100L according to a twelfth embodiment of the disclosure. Please refer to FIG. 1 and FIG. 12. The display panel 100L of the embodiment is similar to the display panel 100A of the first embodiment. The main difference between the two is that the display panel 100L of the embodiment further includes the carrier C′, a substrate S, a curved connecting conductive line 190′, and the driving chip 150′, wherein the substrate S is disposed on the carrier C′, the first redistribution structure 120 is disposed on the substrate S, the first redistribution structure 120 is electrically connected to the driving chip 150′ on the carrier C′ through the connecting conductive line 190′, and the connecting conductive line 190′ is, for example, a curved gold bonding wire formed by a wire bonder. Furthermore, in the display panel 100L, the width of the first redistribution structure 120 is greater than the width of the second redistribution structure 130.

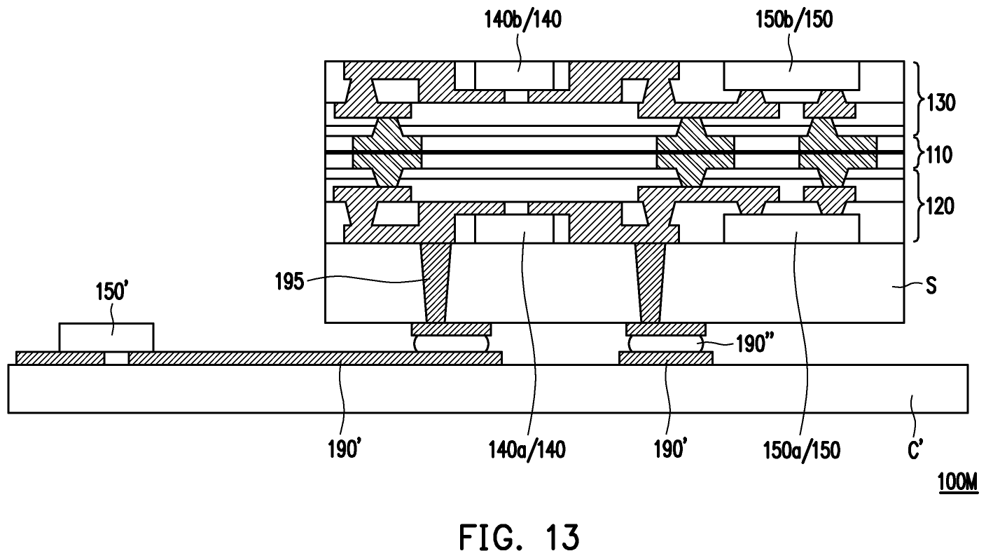

FIG. 13 is a schematic cross-sectional view of a display panel 100M according to a thirteenth embodiment of the disclosure. Please refer to FIG. 12 and FIG. 13. The display panel 100M of the embodiment is similar to the display panel 100L of the twelfth embodiment. The main difference between the two is that the display panel 100M of the embodiment further includes conductive through vias 195 penetrating the substrate S and connecting conductors 190″, wherein the substrate S is disposed above the carrier C′, the first redistribution structure 120 is disposed on the substrate S, and the first redistribution structure 120 is electrically connected to the driving chip 150′ on the carrier C′ through the conductive through vias 195 penetrating the substrate S, the connecting conductors 190″, and the connecting conductive line 190′, wherein the connecting conductors 190″ are, for example, conductive bumps, solder balls, or other forms of conductive terminals.

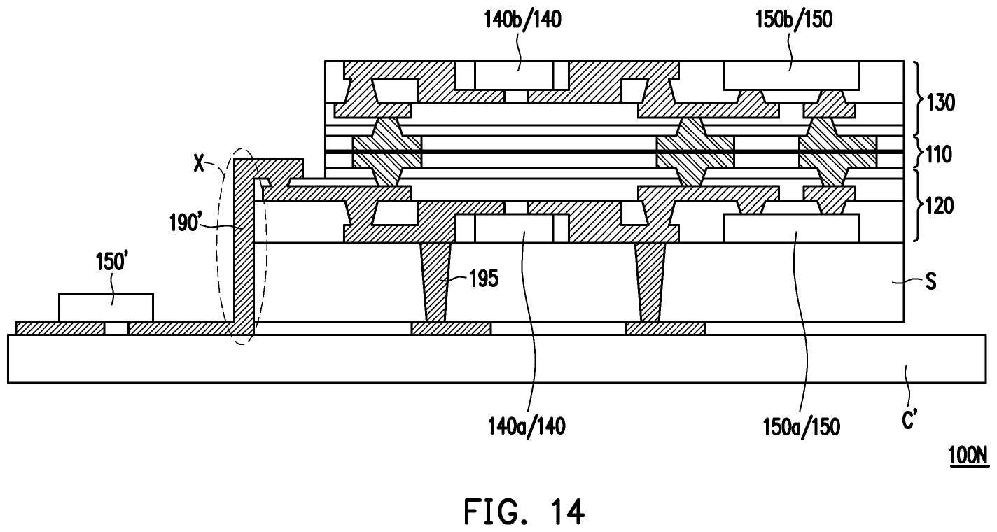

FIG. 14 is a schematic cross-sectional view of a display panel 100N according to a fourteenth embodiment of the disclosure. Please refer to FIG. 13 and FIG. 14. The display panel 100N of the embodiment is similar to the display panel 100M of the thirteenth embodiment. The main difference between the two is that in the display panel 100N of the embodiment, a partial region (for example, an X region) of the connecting conductive line 190′ extends along side walls of the substrate S and the first redistribution structure 120. Furthermore, in the display panel 100N, the width of the first redistribution structure 120 is greater than the width of the second redistribution structure 130.

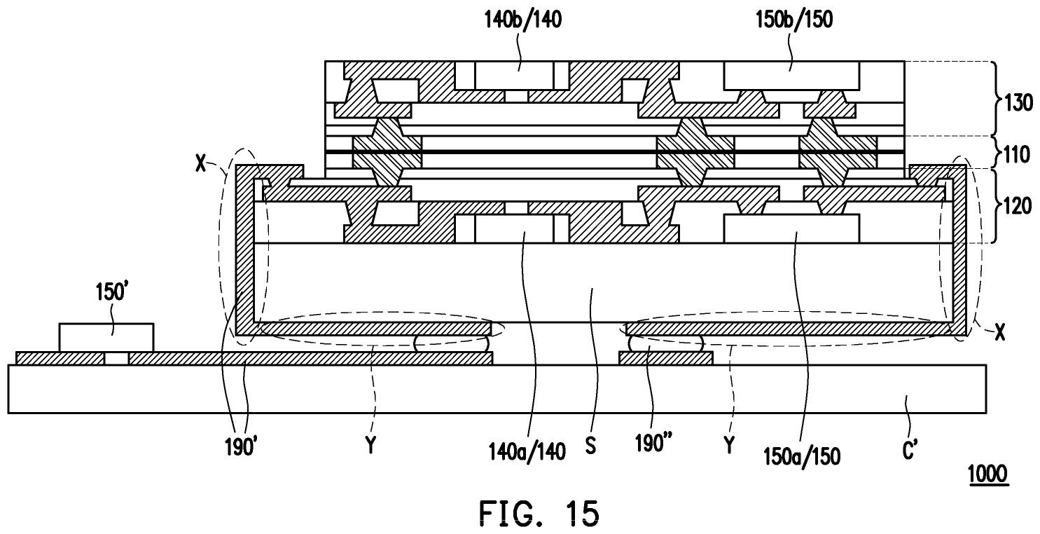

FIG. 15 is a schematic cross-sectional view of a display panel 100O according to a fifteenth embodiment of the disclosure. Please refer to FIG. 13 and FIG. 15. The display panel 100O of the embodiment is similar to the display panel 100M of the thirteenth embodiment. The main difference between the two is that in the display panel 100O of the embodiment, the partial region (for example, the X region) of the connecting conductive line 190′ extends along the side walls of the substrate S and the first redistribution structure 120, and a partial region (for example, a Y region) of the connecting conductive line 190′ extends along a bottom surface of the substrate S to be electrically connected to the connecting conductors 190″.

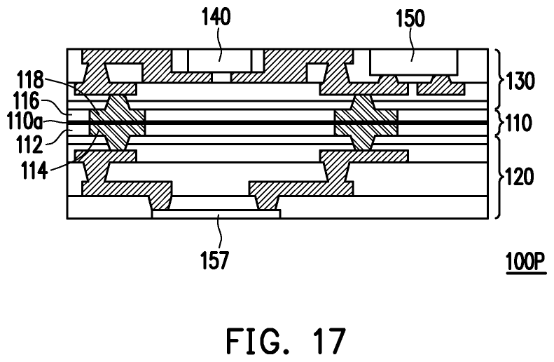

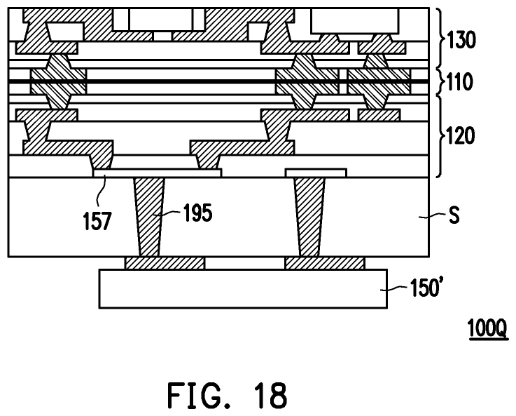

FIG. 17 is a schematic cross-sectional view of a display panel 100P according to a sixteenth embodiment of the disclosure. Please refer to FIG. 1 and FIG. 17. The display panel 100P of the embodiment is similar to the display panel 100A of the first embodiment. The main difference between the two is that in the display panel 100P of the embodiment, the first redistribution structure 120 may further include the active element 157 embedded therein.

FIG. 18 is a schematic cross-sectional view of a display panel 100Q according to a seventeenth embodiment of the disclosure. Please refer to FIG. 18. The display panel 100Q of the embodiment is similar to the display panel 100N of the fourteenth embodiment. The main difference between the two is that the display panel 100Q of the embodiment does not have the carrier C′, and the driving chip 150′ is disposed on the bottom surface of the substrate S to be electrically connected to the first redistribution structure 120 through the conductive through vias 195 of the substrate S. In addition, in the display panel 100N of the embodiment, the first redistribution structure 120 may further include the active element 157 embedded therein.

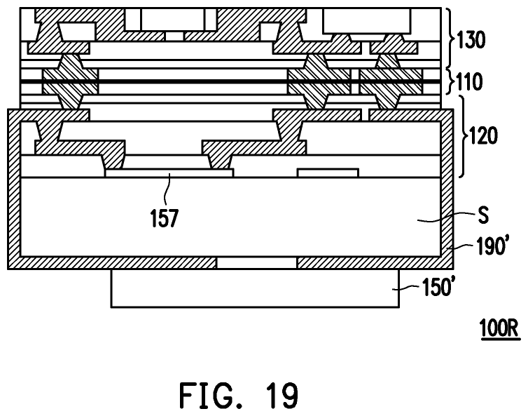

FIG. 19 is a schematic cross-sectional view of a display panel 100R according to an eighteenth embodiment of the disclosure. Please refer to FIG. 19. The display panel 100R of the embodiment is similar to the display panel 100O of the fifteenth embodiment. The main difference between the two is that the display panel 100R of the embodiment does not have the carrier C′, and the driving chip 150′ is disposed on the bottom surface of the substrate S to be electrically connected to the first redistribution structure 120 through the connecting conductive line 190′. In addition, in the display panel 100R of the embodiment, the first redistribution structure 120 may further include the active element 157 embedded therein.

In the above embodiments of the disclosure, in the display panel manufactured by adopting the hybrid bonding process, the light emitting chips, the driving chips, and the active element and/or the passive element operating together with the driving chips may be disposed on the same side or the opposite sides of the hybrid bonding interface according to design requirements, so that the configuration positions of the elements in the display panel are more flexible. In addition, since the hybrid bonding structure has good evenness, the display panel manufactured by adopting the hybrid bonding process can improve issues of display mura and reliability.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A hybrid bonding structure, comprising:
a first dielectric layer;
a plurality of first conductors, embedded in the first dielectric layer;
a second dielectric layer, bonded with the first dielectric layer; and
a plurality of second conductors, embedded in the second dielectric layer, wherein the second conductors are bonded with the first conductors, and a bonding interface between the second conductors and the first conductors is a bonding interface containing silver.

2. The hybrid bonding structure according to claim 1, wherein the bonding interface comprises a copper-silver alloy bonding interface.

3. The hybrid bonding structure according to claim 1, wherein the first conductors penetrate the first dielectric layer, the second conductors penetrate the second dielectric layer, an elongation of the first dielectric layer is approximately between 10% and 85%, a Young's modulus of the first dielectric layer is approximately between 2.5% and 3.2%, a tensile strength of the first dielectric layer is greater than 110 MPa, an elongation of the second dielectric layer is approximately between 10% and 85%, a Young's modulus of the second dielectric layer is approximately between 2.5% and 3.2%, and a tensile strength of the second dielectric layer is greater than 110 MPa.

4. The hybrid bonding structure according to claim 1, further comprising:
a first redistribution structure, disposed on an outer surface of the first dielectric layer; and
a second redistribution structure, disposed on an outer surface of the second dielectric layer, wherein the first redistribution structure is electrically connected to the second redistribution structure through the first conductors and the second conductors.

5. The hybrid bonding structure according to claim 4, further comprising:
a first chip, embedded in the first redistribution structure and electrically connected to the first redistribution structure.

6. The hybrid bonding structure according to claim 5, further comprising:
a second chip, embedded in the second redistribution structure and electrically connected to the second redistribution structure, wherein the first chip and the second chip are respectively located on opposite sides of the bonding interface.

7. The hybrid bonding structure according to claim 5, further comprising:
a second chip, disposed on the second redistribution structure and electrically connected to the second redistribution structure, wherein the first chip and the second chip are respectively located on opposite sides of the bonding interface.

8. The hybrid bonding structure according to claim 1, wherein the first dielectric layer has a plurality of protrusions, the second dielectric layer has a plurality of grooves, and the protrusions are embedded in the grooves.

9. A display panel, comprising:
a hybrid bonding structure;
a first redistribution structure;
a second redistribution structure, wherein the first redistribution structure and the second redistribution structure are respectively located on opposite sides of the hybrid bonding structure, and the first redistribution structure is electrically connected to the second redistribution structure through the hybrid bonding structure;
a plurality of light emitting chips; and
a plurality of driving chips, wherein the driving chips are electrically connected to the light emitting chips through at least one of the first redistribution structure and the second redistribution structure.

10. The display panel according to claim 9, wherein the light emitting chips comprise a plurality of first light emitting chips and a plurality of second light emitting chips, the driving chips comprise a plurality of first driving chips and a plurality of second driving chips, the first light emitting chips and the first driving chips are embedded in the first redistribution structure, and the second light emitting chips and the second driving chips are embedded in the second redistribution structure.

11. The display panel according to claim 10, wherein the hybrid bonding structure comprises:
a first dielectric layer;
a plurality of first conductors, embedded in the first dielectric layer;
a second dielectric layer, bonded with the first dielectric layer; and
a plurality of second conductors, embedded in the second dielectric layer, wherein the second conductors are bonded with the first conductors, the first dielectric layer has a plurality of protrusions, the second dielectric layer has a plurality of grooves, the protrusions are embedded in the grooves, and a bonding interface between the second conductors and the first conductors is a bonding interface containing silver.

12. The display panel according to claim 9, wherein the light emitting chips are embedded in the first redistribution structure, and the driving chips are embedded in the second redistribution structure.

13. The display panel according to claim 9, wherein the light emitting chips are embedded in the first redistribution structure, the driving chips are disposed on the second redistribution structure, and the light emitting chips are electrically connected to the driving chips through the first redistribution structure, the hybrid bonding structure, and the second redistribution structure.

14. The display panel according to claim 9, wherein the light emitting chips and the driving chips are embedded in the first redistribution structure, and the light emitting chips are electrically connected to the driving chips at least through the first redistribution structure.

15. The display panel according to claim 9, further comprising:
a flexible material layer, disposed on the first redistribution structure.

16. The display panel according to claim 9, further comprising:
a first substrate, disposed on the first redistribution structure; and
a second substrate, disposed on the second redistribution structure, wherein the first redistribution structure and the second redistribution structure are located between the first substrate and the second substrate.

17. The display panel according to claim 9, wherein a width of the first redistribution structure is greater than or equal to a width of the second redistribution structure.

18. A display panel, comprising:
a redistribution structure;
a plurality of light emitting chips, embedded in the redistribution structure;
a plurality of driving chips, equipped on the redistribution structure, wherein the driving chips are electrically connected to the light emitting chips through the redistribution structure; and
a carrying substrate, wherein the driving chips are located between the redistribution structure and the carrying substrate.

19. The display panel according to claim 18, further comprising a stress compensation layer disposed between the driving chips and the carrying substrate.

20. The display panel according to claim 18, wherein the carrying substrate comprises a groove, and the driving chips are located in the groove.
